(19) United States
(12) Patent Application Publication
(10) Pub. No.: US 2017/0202112 A1
(43) Pub. Date: Jul. 13, 2017

(54) Rack server for a server rack

(71) Applicant: FUJITSU LIMITED, Kawasaki-shi (JP)

(72) Inventors: Gerhard Mühsam, Königsbrunn (DE); Reinhard Salmen, Lichtenau (DE); Albert Schaur, München (DE); Sebastian Schilling, München (DE)

(73) Assignee: FUJITSU LIMITED, Kawasaki-shi (JP)

(21) Appl. No.: 15/468,752

(22) Filed: Mar. 24, 2017

Related U.S. Application Data
(63) Continuation of application No. PCT/EP2016/051013, filed on Jan. 19, 2016.

(30) Foreign Application Priority Data
Jan. 29, 2015 (DE) 102015101304.5

(51) Int. Cl. H05K 7/20

(52) U.S. Cl. CPC H05K 7/20736

(57) ABSTRACT

A rack server that includes a housing having a front side and a rear side. A main board arranged in the housing is provided with at least one processor, on which a heat sink is arranged. Furthermore, fans are arranged in the housing upstream of the processor with respect to the insertion direction and suck cooling air into the housing via the front side and blow towards the rear side. The rack server includes a power supply in the housing downstream of the processor with respect to the insertion direction. An air guide element is arranged in the housing between the power supply and the heat sink in such a way that cooling air supplied to the heat sink is guided past the power supply to the rear side of the housing and cooling air supplied to the power supply is not preheated by the heat sink.

The invention relates to a rack server for a server rack, which comprises a housing having a front side and a rear side, which is insertable in the server rack in an insertion direction towards the rear side.

Computer systems, e.g. workstations or servers, generate a relatively high amount of heat in operation, which has to be discharged for safe operation of the respective computer system. A main heat source is one or multiple processor of a computer system. Regions of the processors inside a housing of the computer system can thus be regarded as critical zones, which have to be cooled in a specific manner. In addition, components located close-by inside the housing of the computer system can be affected by the waste heat of the processors, for example.

One object underlying the invention is to describe a server for a server rack, which is characterized by an efficient cooling concept.

The object is achieved by a server for a server rack. The server comprises a housing having a front side and a rear side, which is insertable into the server rack in an insertion direction towards the rear side. The server comprises a main board arranged in the housing and having at least one processor with a heat sink arranged thereon. Furthermore, the server comprises a plurality of fans, which are arranged in the housing upstream of the processor with respect to the insertion direction, and which are each configured to suck cooling air into the housing via the front side and blow it towards the rear side. Furthermore, the server comprises a power supply unit, which is arranged in the housing downstream of the processor with respect to the insertion direction. In addition, the server comprises an air guide element, which is arranged in the housing between the power supply unit and the heat sink in such a way that cooling air supplied to the heat sink of the processor is guided past the power supply unit to the rear side of the housing and cooling air supplied to the power supply unit is not preheated by the heat sink of the processor.

The server enables a simple installation and particularly efficient and effective cooling of its components. The cooling system of the server is a so-called front-to-back cooling system, in which the fans suck cooling air from the front side and discharge it via the rear side of the housing. The plurality of fans is arranged in front of the processor and its heat sink with respect to the insertion direction, while the at least one power supply unit is arranged in a region of the housing behind the processor and its heat sink. Thus, part of the cooling air sucked by the fans hits the heat sink of the processor first and flows around or through this heat sink. The cooling air heated thereby is guided past the at least one power supply unit by means of the air guide elements. This prevents that the air heated by the heat sink of the processor is supplied to the at least one power supply unit. This prevents the power supply unit from overheating, since it receives only cooling air that has essentially not been preheated by the heat sink of the processor, which flows through the power supply unit for cooling the same and which is discharged via the rear side of the housing. The cooling air for the power supply unit is generated by one or multiple other fans, which are not provided for the cooling of the processor and its heat sink. In other words, the air guide element separates cooling airflows, so that a targeted cooling of critical zones and/or certain components of the server is achieved. Altogether, the air guide element ensures that the power supply unit is sufficiently cooled.

Furthermore, a power consumption of the server can be reduced on the whole by the provision of the air guide element, since the fan of the power supply unit typically present in the power supply unit is to be operated at a lower rotational speed for the cooling of the power supply unit.

The air guide element has a modular design, so that it can be used in the server as required.

The majority of fans is a so-called fan bank, in which the fans are arranged in a row and suck air into the housing essentially over the entire cross-section of the housing. However, alternatively, it is conceivable that the fans are arranged offset to one another. Optionally, the fans are not arranged over the entire width of the housing, but only in a partial region.

According to one embodiment, the server comprises a scoop, which is securable to the heat sink of the processor and at least one fan, so that an air channel is formed between the heat sink and the at least one fan together with the main board. The scoop allows guiding a cooling air flow of a fan to the heat sink of the processor in a targeted manner. This ensures the heat sink to be sufficiently cooled. As an alternative, it is also conceivable to configure the scoop in such a way that the cooling airflow of two fans or multiple fans is exclusively supplied to the heat sink. Optionally, the scoop has a modular design and can be used in the server as required, in order to ensure a cooling air flow to be guided to the heat sink in a target manner.

According to another embodiment, the air guide element terminates with the main board and a cover of the housing server housing in a form-fit manner. This ensures that cooling airflows guided on both sides of the air guide element do not interfere with one another or be mixed. The cooling air flow separation is enabled thereby, so that a separate cooling air flow of one or multiple fans arrives at the power supply unit.

According to another embodiment, the air guide element is configured as a wall. For example, this wall has a thin-wall profile. Depending on the arrangement of the power supply unit behind the heat sink of the processor, the air guide element comprises angled, bent curved sections for guiding the cooling air. Thus, the air guide element can be adapted to the structural conditions of the server, e.g. the physical design, arrangement of the components in the housing and components on the main board, in order to effect the reliable air guidance. According to another embodiment, the power supply unit is at least partially arranged directly opposite the heat sink. In such an arrangement, the air heated by the heat sink of the processor would almost directly be supplied to the power supply unit. This would particularly contribute to an overheating pf the power supply unit. This is prevented by the provision of the air guide element, which is arranged between the power supply unit and the heat sink in such a way that the cooling air heated by the heat sink is guided past the power supply unit. Here, it may be required to adjust the air guide element accordingly in terms of its profile, as described above.

According to another embodiment, the air guide element can be secured in the housing without tools. Thus, the air guide element can be mounted in the housing in simple ways and manners, without elaborate measures such as screwing, riveting, soldering, or the like being required.

According to another embodiment, the air guide element latches with the scoop and/or a cage housing, in which the power supply unit is arranged. For example, the air guide element latches with an element, namely the scoop or the cage housing, while being connected to the other element in a form-fit manner. For example, the air guide element is inserted with a correspondingly shaped lug in a reception opening formed in a wall of the cage housing in a form-fit manner. The reception opening is designed in the type of a pocket, for example.

According to another embodiment, the scoop can be secured to the heat sink and the at least one fan without tools. In particular, the scoop latches with one or both elements. This ensures a simple mounting process in analogy to the above.

According to another embodiment, the air guide element is made of a plastic material. For example, an ABS-PC blend plastic material is used.

Optionally, the scoop can be made of a plastic material. For example, a transparent plastic can be used, so that LEDs arranged on the main board are visible through the scoop. This is suitable in error detection, for example, in which the LEDs indicate corresponding error codes. In this case, the scoop does not have to be dismounted, with the LEDs being visible through the scoop.

According to another embodiment, the server has a construction height of one unit (1U). Cooling is particularly difficult in such compact and small servers, in particular blade servers, due to the compact and narrow arrangement of the components. A particularly efficient cooling is ensured by means of the air guide element despite the narrow space available.

Further embodiments of the invention are indicated in the following detailed description of an exemplary embodiment.

The exemplary embodiment will be described using the attached figures.

The figures show in:

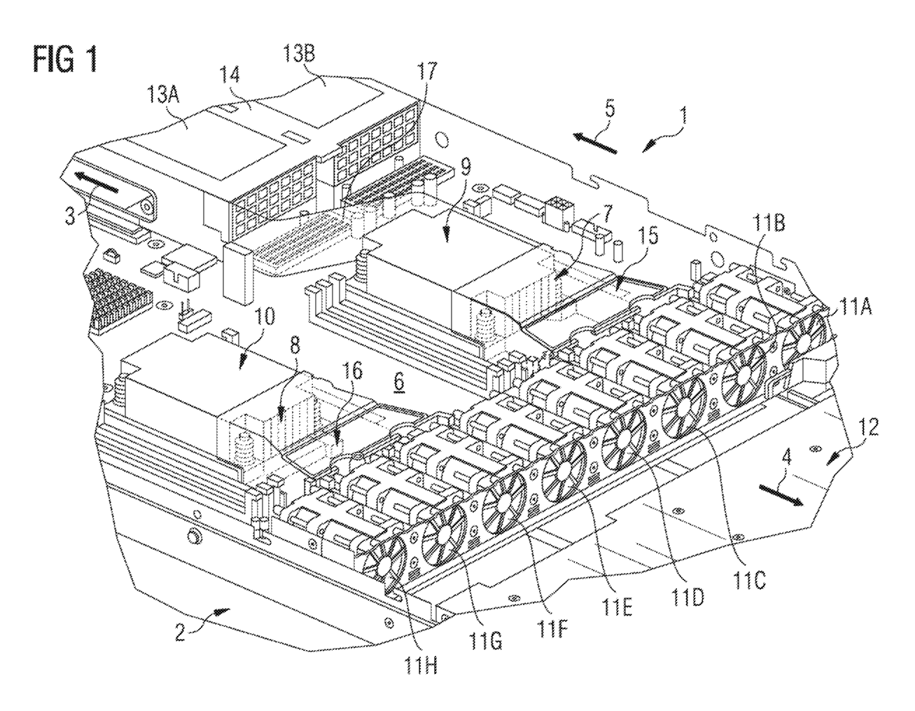

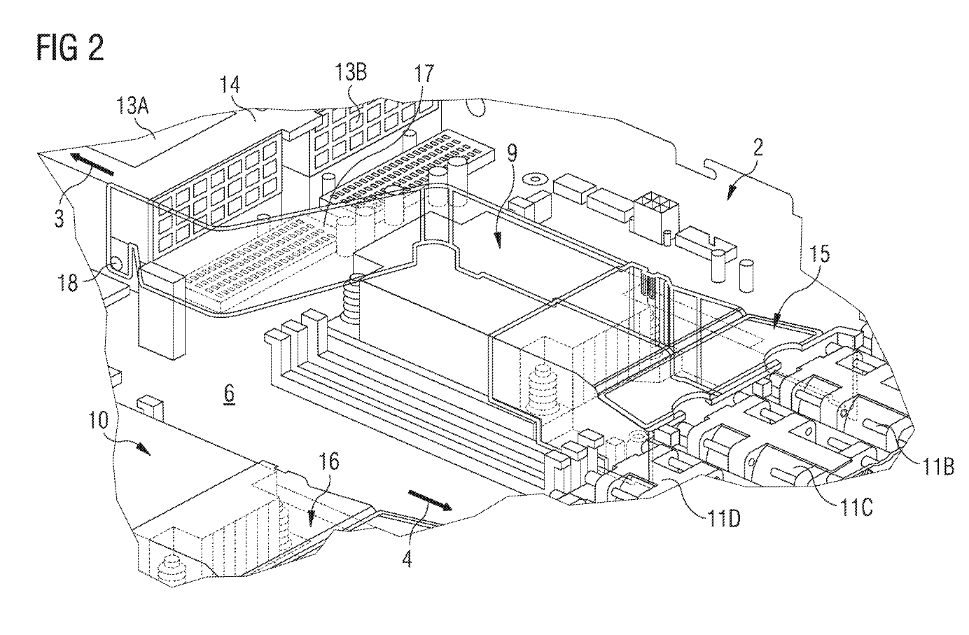

FIGS. 1 and 2 two perspective views of a rack sever having an air guide element according to an exemplary embodiment of the invention.

FIGS. 1 and 2 show a rack server 1 for a server rack in a perspective view. The rack server 1 has a housing 2, in which a cover was removed for illustration purposes. The housing 2 comprises—indicated by arrows—a rear side 3 as well as a front side 4. The rack server 1 can be inserted into the server rack in an insertion direction 5 towards the rear side 3. The housing has a construction height of one 1U, (1 unit).

A plurality of components is compactly arranged in the housing 2 in confined spaces. A main board 6 is secured in the housing 2, with a first processor 7 as well as a second processor 8 mounted thereon. In each case one heat sink is arranged on the two processors 7 and 8, namely a first heat sink 9 and a second heat sink 10, respectively. These cooling bodies 9, 10 almost completely cover the two processors 7 and 8 in FIGS. 1 and 2.

Furthermore, a plurality of fans 11A to 11H is mounted in the housing 2 of the rack server 1, the fans forming a fan bank.

The fans 11A to 11H are arranged over the entire width of the housing 2. With respect to the insertion direction 5, multiple storage drives 12 are arranged in front of the fans 11A to 11H over the entire width of the housing 2. The two processors 7 and 8 with their cooling bodies 9 and 10 are arranged behind the fans 11A to 11H. With respect to the insertion direction 5, two power supply units 13A and 13B are arranged farther in the back of the housing 2. The power supply units 13A and 13B are installed within a cage housing 14. The power supply units 13A and 13B each have a distinct fan of the power supply unit for the cooling thereof.

The fans 11A and 11H ensure a so-called font-to-back cooling system, in which cooling air is sucked in the housing 2 via the front side 4. This cooling air is blown in the insertion direction 5 towards the rear side 3 and discharged via this side.

Due to the compact design of the rack server 1, efficient cooling of the server is required. The processors 7 and 8 typically are the strongest heat source and therefor have to be cooled in an especially targeted manner. To that end, in each case one scoop 15 or 16 is provided for each heat sink. The scoops 15 and 16 are each formed of a transparent plastic material and are mounted without tools. To that end, the scoops 15, 16 latch with the two fans 11B, 11C or 11F, 11G as well as the heat sink 9. Here, the scoops 15 and 16 enclose the corresponding heat sink 9 or 10 from at least three sides in a form-fit manner and form a channel, in particular an air channel, together with the main board 6. The scoops 15 and 16 also enclose in each case two fans 11B and 11C or 11F and 11G. This ensures that the cooling air generated by the fans 11B and 11C or 11F and 11G is directly and essentially exclusively supplied to the processors 7, 8 or their cooling bodies 9, 10.

The use of in each case two fans 11B and 11C, respectively 11F and 11G, achieves a fan redundancy, so that if of one of the two fans 11B, 11C, 11F or 11G assigned to a heat sink 9 or 10 fails, nevertheless a sufficient cooling is ensured at least temporarily.

Due to the arrangement of the power supply units 13A and 13B, which are arranged to be downstream the first heat sink 9 and the first processor 7, a sufficient cooling of the two power supply units 13A and 13B could not be ensured, since the cooling air heated by the processor 7, respectively the first heat sink 9, would at least in a large part be supplied to the two power supply units 13A and 13B. This would result in the preheated air being able to absorb less heat energy generated by the power supply units 13A and 13B.

In order to prevent that this leads to an overheating of the power supply units 13A and/or 13B, an air guide element 17 is arranged in the rack server 1, which guides cooling air heated by the first processor 7 or the first heat sink 9 past the two power supply units 13A and 13B.

FIG. 2 shows the air guide element 17 as well as the scoop 15, showing through by its edges, in detail. The air guide element 17 is latched with the scoop 15 at one end. It is inserted in a corresponding reception opening or pocket of the cage housing in a form-fit manner with the other end by means of a lug 18. The air guide element 17 is configured such that it essentially terminates flush with the main board 6 and/or components on the main board 6. A further form-fit is achieved by placing-on a cover of the housing 2 between the air guide element 17. As a result, the housing 2 is divided fluidicly in operation of the rack server 4.

The first fan 11A is used essentially for cooling the two power supply units 13A and 13B, while the further fans 11B to 11H generate a cooling airflow, particularly due to the air guide element 17, which is not mixed with the one of the first fan 11A. In particular, the cooling air heated by the first processor 7, which is generated exclusively by the two fans 11B and 11C, is guided past the two power supply units 13A and 13B by the air guide element 17. To that end, the air guide element 17 has a bent and/or angled profile between the first heat sink 9 and the power supply units 13A, 13B. Thus, the cooling air supplied to the power supply units 13A and 13B is not preheated by the first processor 7 and/or the second processor 8. An overheating of the two power supply units 13A and 13B is prevented thereby.

It bis to be noted that the cooling airflow generated by the first fan 11A can also absorb heat from elements or components arranged on the main board 6. These include storage banks or the like, for example. This heat absorption can be neglected compared to a heat absorption via a heat sink 9 or 10 and would not negatively affect a sufficient cooling of the power supply units 13A and 13B.

Thus, the described rack server enables efficient cooling of all of its components and prevents that so-called hotspots or critical heat zones are generated inside the housing 2. Furthermore, energy consumption of the two fans of the power supply units 13A and 13B can be reduced or even prevented.

The air guide element 17 is required in particular in the region of the housing 2, where the power supply units 13A, 13B are essentially arranged directly opposite a processor or the heat sink thereof, as in the case of the first processor 7 according to FIGS. 1 and 2. As used herein, the term “directly opposite” means that cross-sections of the corresponding processor 7 and the heat sink 9 as well as of the power supply units 13A, 13B at least partially overlap or only insignificantly not overlap projected into a plane, the plane running normal to the insertion direction 5. In other words, this means the zone behind the processor 7 or heat sink 9, which is significantly influenced by the cooling air heated by the heat sink 9. In this zone, the cooling air heated by the processor 7 would flow toward the power supply units 13A, 13B due to its flow direction, which essentially coincides with the insertion direction 5.

Optionally, the second processor 8 as well as its heat sink 10 and the scoop 16 assigned to it can be omitted.

In an exemplary embodiment, which is not shown, one or two scoops 15, 16 is/are mounted around only one fan, instead of two fans.

In another exemplary embodiment, which is not shown, two or more fans are used for cooling the power supply units 13A and 13B. Depending on the requirements and the required cooling, more cooling air is provided thereby for cooling the power supply units 13A and 13B.

### List of Reference Numerals

1 Rack server

2 Housing

3 Rear side

4 Front side

5 Insertion direction

6 Main board

7 First processor

8 Second processor

9 First heat sink

10 Second heat sink

11A bis 11H Fan

12 Storage medium

13A, 13B Power supply unit

14 Cage housing

15, 16 Scoop

17 Air guide element

18 Lug

1. Rack server for a server rack, comprising
a housing having a front side and a rear side, which housing can be inserted in the server rack in an insertion direction towards the rear side;
a main board arranged in the housing having at least one processor, on which a heat sink is arranged;
a plurality of fans, which are arranged in the housing upstream of the processor with respect to the insertion direction and which are each configured to suck cooling air into the housing via the front side and to blow it towards the rear side;
a power supply unit, which is arranged in the housing downstream of the processor with respect to the insertion direction, wherein the power supply unit is at least partially arranged directly opposite the heat sink; and
an air guide element, which is arranged in the housing between the power supply unit and the heat sink in such a way that cooling air supplied to the heat sink of the processor is guided past the power supply unit to the rear side of the housing and cooling air supplied to the power supply unit is not preheated by the heat sink of the processor.

2. Rack server according to claim 1, comprising an air scoop, which is securable to the heat sink and at least one fan, so that an air channel is formed between the heat sink and the at least one fan together with the main board.

3. Rack server according to claim 1, wherein the air guide element terminates with the main board and a cover of the housing in a form-fit manner.

4. Rack server according to claim 1, wherein the air guide element is formed as a wall.

5. Rack server according to claim 1, wherein the air guide element can be secured in the housing without tools.

6. Rack server according to claim 1, wherein the air guide element latches with the scoop and/or with a cage housing, in which the power supply unit is arranged.

7. Rack server according to claim 2, wherein the scoop can be secured to the heat sink and the at least one fan without tools.

8. Rack server according to claim 1, wherein the air guide element is made from a plastic material.

9. Rack server according to claim 1, wherein the rack server has a construction height of one unit.

10. Rack server according to claim 2, wherein the air guide element terminates with the main board and a cover of the housing in a form-fit manner.

11. Rack server according to claim 2, wherein the air guide element latches with the scoop and/or with a cage housing, in which the power supply unit is arranged.
